(19) United States
(12) Patent Application Publication
(10) Pub. No.: US 2013/0344654 A1
(43) Pub. Date: Dec. 26, 2013

(54) Process For Flip-Chip Connection of an Electronic Component

(71) Applicants: Olivier Limousin, Palaiseau (FR); Fabrice Soufflet, Bievres (FR)

(72) Inventors: Olivier Limousin, Palaiseau (FR); Fabrice Soufflet, Bievres (FR)

(73) Assignees: 3D Plus, Buc (FR); Commissariat A L'Energie Atomique Et Aux Energies Alternatives, Paris (FR)

(21) Appl. No.: 14/003,940

(22) PCT Filed: Mar. 6, 2012
(86) PCT No.: PCT/IB2012/051048

§ 371 Date: Sep. 9, 2013

(30) Foreign Application Priority Data
Mar. 10, 2011 (FR) 1100719

(51) Int. Cl. H01L 23/00

(52) U.S. Cl. CPC H01L 24/03
USPC 438/108

(57) ABSTRACT

The invention relates to a process for flip-chip connection of an electronic component (D) to a substrate (B), characterized in that it comprises producing at least one interconnect pad (PC) by etching a thick conductive film and bonding it, by means of at least one conductive adhesive, between a receiving pad or area of said electronic component and a receiving pad or area (PAS) of said substrate.

The invention relates to a flip-chip process for interconnecting an electronic component and a substrate.

Flip-chip interconnection is an interconnect technique that is very widely used in electronics. In its most conventional form it comprises depositing solder balls on interconnect lands, typically located on the frontside of a chip, flipping said chip such that said frontside is oriented toward the mounting surface of a substrate, itself comprising interconnect lands, bringing the chip into contact with said substrate, and then applying heat in order to melt the solder balls and thus produce a permanent interconnect. Relative to the wire bonding interconnect technique, flip-chip connection of a chip enables advanced miniaturization of electronic circuits and makes it possible to reduce parasitic inductances. In contrast, this technique also has its drawbacks, among which mention may be made:
applying a high temperature (generally above 100° C. and often above 200° C.) in immediate proximity to the electronic chip may lead to degradation of the latter; this problem has been exacerbated, since 2006, by the banning of lead-containing solders;
the need to strengthen the assembly by filling the space between the chip and the substrate with a dielectric “underfill” resin, thereby possibly introducing parasitic capacitances and/or dielectric losses or even contaminating certain sensitive components of the chip such as sensors; and
a high sensitivity to thermomechanical stresses generated by the differential thermal expansion of the chip and substrate, which stresses may lead to interconnects being broken. This problem is worsened by the fact that the interconnects are small in height; documents U.S. Pat. No. 5,598,036 and U.S. Pat. No. 6,657,134 disclose double interconnect techniques allowing said height to be increased, and therefore thermomechanical stresses to be limited. However, these processes are complex to implement.

Variants of the flip-chip interconnect technique use conductive adhesives, generally epoxy resins filled with a metal powder (commonly called “conductive epoxy resins”), to interconnect a chip and a substrate, thus replacing the solder balls. These techniques make it possible to work at low temperatures, and are therefore recommended for the bonding of very fragile chips, such as the CdTe X-ray sensors used in medical imaging and for space applications. Furthermore, the polymer materials used may have lower Young's moduli than metals, thereby contributing to limiting thermomechanical stresses.

Techniques based on the screen printing of a conductive adhesive, such as described in document U.S. Pat. No. 5,074,947, result in pads having a low aspect ratio (defined as the ratio between the height and the smallest of their lateral dimensions), of about 0.1. Thus, pads of large height (100 μm or more), which may prove to be necessary to keep thermomechanical stresses to an acceptable level, must have a very large area and therefore a low interconnect density. In addition, the maximum height is limited by the area of the smallest pad; the technique is therefore unsuitable for irregular interconnect patterns requiring different sizes of interconnect pads that are sometimes located very close to one another.

Document U.S. Pat. No. 7,109,107 describes a lithography technique for manufacturing pads made of a conductive epoxy resin. This technique allows pads having a high aspect ratio (up to four) to be produced; however, the height of these pads is limited to about 16 μm.

The invention aims to remedy the aforementioned drawbacks of the prior art.

The subject of the invention, making it possible to obtain this aim, is a flip-chip process for interconnecting an electronic component and a substrate, characterized in that it comprises producing at least one interconnect pad by etching a thick conductive layer and adhesively bonding it, by means of at least one conductive adhesive, between a receiving pad or land of said component and a receiving pad or land of said substrate.

The electronic component may be a bare or encapsulated chip, a sensor, a hybrid circuit, an integrated circuit, etc.

In particular, the electronic component may be a chip. The term “chip” is understood to mean any electronic circuit or component produced from a semiconductor wafer. It could be an integrated circuit but also a sensor, especially a matrix sensor.

The substrate may be a printed circuit board, a three-dimensional electronic unit consisting of a stack of chips and/or printed circuit boards embedded in a resin, or even a chip.

The expression “thick layer” is understood to mean a self-supporting layer. The thickness from which a layer may be considered to be “thick” therefore depends on the material in question.

The process of the invention allows the definition of the thickness of the conductive pads to be disassociated from their geometry in the plane of the substrate and of the component.

A first variant of the process of the invention comprises the following steps:
(a) manufacturing a thick conductive layer;
(b) adhesively bonding it, by means of a conductive adhesive, to an area of an electronic component or of a substrate having at least one receiving pad or land;
(c) producing at least one interconnect pad, in correspondence with said or each receiving pad or land to be connected, by etching said thick layer and said thin layer of conductive adhesive; and
(d) adhesively bonding, by means of a conductive adhesive, said or each interconnect pad to a respective receiving pad or land of a substrate or of an electronic component to be interconnected with said electronic component or said substrate, respectively.

A second variant of the process of the invention comprises the following steps:
(A) manufacturing a thick conductive layer;
(B) adhesively bonding it to a temporary substrate;
(C) etching said thick layer, bonded to said temporary substrate, in order to form an interconnect pattern comprising at least one interconnect pad;
(D) bonding, by means of a conductive adhesive, said or each interconnect pad to a respective receiving pad or land of a substrate or of an electronic component;
(E) debonding said or each interconnect pad from said temporary substrate; and
(F) bonding, by means of a conductive adhesive, said or each interconnect pad to a respective receiving pad or land of a substrate or of an electronic component to be interconnected electronic component with said electronic component or said substrate, respectively.

In various embodiments of the process of the invention:
said thick layer may have a thickness larger than or equal to 100 μm, thereby allowing the thermomechanical stresses generated by the differential thermal expansion of the electronic component and the substrate to be largely limited;
said or at least one said interconnect pad may have a height at least equal to half the smallest of its lateral dimensions, i.e. an aspect ratio of 0.5 or more. Even more preferably, the aspect ratio may be 1 or more;
said process may comprise a step of setting (especially by polymerizing or cross-linking) said or at least one said conductive adhesive at a temperature of 40° C. or less. The expression “setting” is understood to mean the passage of the adhesive from a viscous state to a solid or rubbery state;
said thick layer may consist of said or a said conductive adhesive used for its adhesive bonding, in the set (for example polymerized or cross-linked) state. This has the advantage of resulting in perfectly homogenous pads in which no adhesive/thick-layer interface is detectable, these pads therefore being stronger from a mechanical point of view;
said or at least one said conductive adhesive may be an epoxy resin containing a conductive filler;
said or each conductive adhesive may be deposited by screen printing on a free surface of the pad produced by etching said thick layer and/or on a receiving pad or land of the chip and/or of the substrate;
said or each interconnect pad may be produced by laser etching said thick layer; and
advantageously, neither said or each said conductive adhesive nor said thick conductive layer should contain lead.

A process according to one preferred embodiment of the invention may allow at least one component having interconnect pads of arbitrary size and shape (round or square pads, etc.; identical or different to one another) arranged arbitrarily (in a matrix, a line, etc.) and with a high interconnect density (for example, with a pitch as small as about 300 μm, isolated by about 100 μm) to be interconnected with a substrate of any nature and any thickness having, facing the pads of the component, receiving lands arranged with a corresponding pattern and making a mechanical and/or electrical connection possible. The interconnect pads may have a relatively large height (100 μm, even much more) and an equally high aspect ratio (typically as high as three), thereby limiting mechanical and thermomechanical stresses and thus allowing components and substrates having very different thermoelastic properties (for example, a large difference between the thermal expansion coefficients of the facing materials) to be connected. Moreover, the interconnection may advantageously be carried out at a low temperature (40° C. or less), without a lead-containing solder and without using an underfill.

Other features, details and advantages of the invention will become apparent on reading the description given with reference to the appended drawings, which are given by way of example, and which show, respectively:

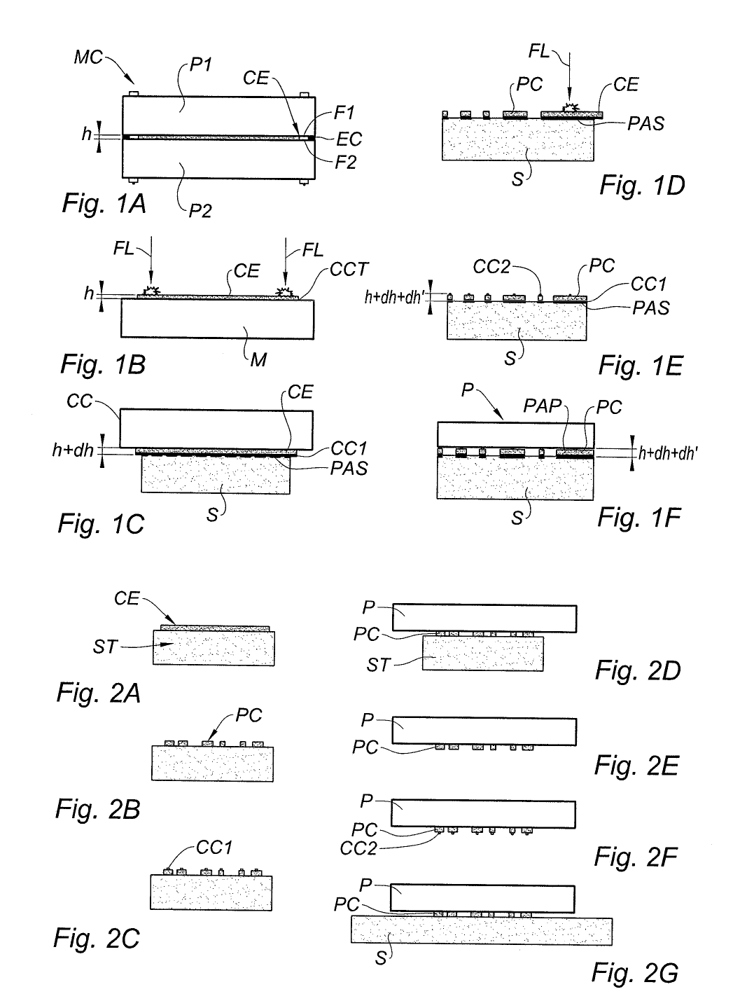

FIGS. 1A-1F, various steps of a process according to a first embodiment of the invention;

FIGS. 2A-2G, various steps of a process according to a second embodiment of the invention; and

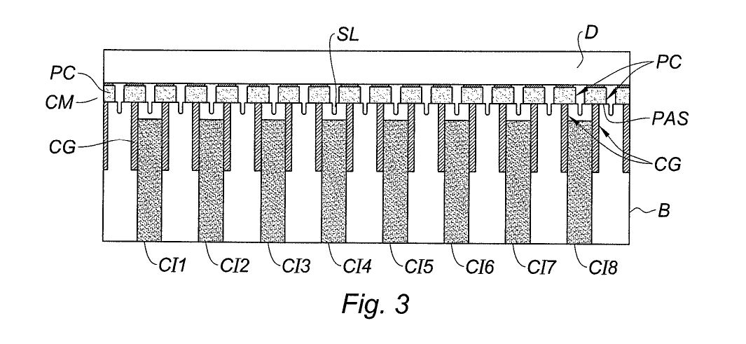

FIG. 3, a view of a detail of an assembly consisting of an X-ray image sensor and a three-dimensional signal processing unit, produced using a process according to the invention.

FIG. 1A illustrates the manufacture by moulding of a thick conductive layer CE used to produce interconnect pads, in a first embodiment of the invention.

The calibrated mould MC comprises:
two right metal plates P1 and P2, for example made of brass, aluminum or stainless steel, arranged facing each other and fastened by bolts and nuts;
two non-stick films F1, F2—for example 50 μm-thick films of polytetrafluoroethylene—entirely covering the opposed sides of the two plates; and
calibrated spacers EC, for example of a height h=200 μm+/−20 μm, placed on the non-stick films in order to define a moulding space of calibrated height between said films.

An adhesive or two-component epoxy resin, made conductive by adding a metal filler, premixed and preferably degassed (or “debubbled”) in a primary vacuum, is injected into the moulding space, subjected to pressure by tightening the fastening bolts, and polymerized. At this stage, the polymerization may be a thermal polymerization, for example at 80° C. for 8 hours. After the mould has been opened, a thick conductive membrane or layer CE may be removed, which layer or membrane will be used to manufacture the interconnect pads.

The choice of the epoxy resin used to produce the thick layer CE depends on the envisioned application. Preferably, this resin may have the following thermomechanical and physico-chemical properties:
a glass transition temperature below the minimum operating temperature of the electronic component, and a Young's modulus of 200 MPa or less and preferably 100 MPa or less, when set;
a shear strength of 10 MPa or more; and
a volume resistivity of 0.05 ohm·cm or less.

It could for example be the adhesive Epotek H20F, which uses a conductive filler made of silver.

A two- or one-component epoxy resin, or even a silicone, polyimide, acrylate, polyester, etc. adhesive, with a conductive filler made of silver, gold, nickel, etc. will possibly be used in various variants of the invention.

FIG. 1B shows the thick conductive layer CE just placed on an intermediate “sacrificial” substrate M in order to be prescored by laser (the laser beam FL for example having a wavelength of 1064 nm, and possibly being generated by a Nd:YAG, or neodymium-doped yttrium aluminum garnet, laser). The “sacrificial” substrate may for example be made of glass with a planarity better than 20 μm. This prescoring step is optional.

In the following step, illustrated in FIG. 1C, the prescored thick conductive layer CE is brought into contact with the substrate S and adhesively bonded to the latter by means of a conductive adhesive deposited on the layer CE itself and/or on the substrate S, the conductive adhesive forming a layer CC1 of thickness dh. Typically, the thickness dh is less than or equal to a tenth of that, h, of the thick layer. Advantageously, the conductive adhesive may be the same used to manufacture the layer CE; in any case, it must be able to adhere to the “receiving” metal lands or pads PAS present on the surface of the substrate S. The adhesive bonding is accompanied by a compression of the thin layer on the substrate by way of a block CC.

Next, as shown in FIG. 1D, a set interconnect pattern is etched into the thick layer CE with a laser (the beam FL may be the same used in the prescoring step, though this is not essential) in order to define conductive pads PC in correspondence with the receiving metal lands or pads PAS on the surface of the substrate. This laser etching step is delicate because it is necessary to completely remove the conductive adhesive beyond the conductive pads PC, in order to prevent short-circuits, without however damaging the surface of the substrate.

The following step, shown in FIG. 1E, comprises localized deposition of a thin layer CC2 of conductive adhesive on the free surfaces of the conductive pads PC. The adhesive may typically be the same used for the layer CC1 and optionally for the thick layer CE; in any case, it must be able to adhere to the receiving metal lands or pads PAP present on the surface of the chip P to be attached. The thickness dh′ of the layer CC2 is typically of the same order of magnitude as dh, and very much smaller than h. Localized deposition of the conductive adhesive may be achieved by screen printing.

Next, FIG. 1F illustrates flip-chip bonding of a chip P having receiving lands or pads PAP in correspondence with conductive pads PC; this bonding operation is a conventional operation. The interconnection is strengthened by applying pressure—possibly a relatively small amount, about 100 or 200 g/cm² or even less—and by polymerizing the adhesive of the layers, preferably at a low temperature (for example at 35° C. for 3 days) in order not to damage the chip.

As a variant, the layer CE may first be adhesively bonded to the chip P, and then etched, in which case the substrate S is flip-bonded.

FIGS. 2A to 2G illustrate an alternative embodiment of the process of the invention, particularly suitable for the case where the substrate is very sensitive to laser ablation of the layer CE.

The steps of manufacturing and optionally prescoring the thick layer CE are not shown; they correspond to those described above with reference to FIGS. 1A and 1B. Said layer CE is temporarily fixed to a temporary substrate ST; the latter may for example consist of a thermal release adhesive such as the Nitto RevAlpha 3195V release tape (FIG. 2A). Next, an interconnect pattern is etched in the layer CE with a laser in order to form conductive pads PC (FIG. 2B). A thin layer CC1 of conductive adhesive is locally deposited, for example by screen printing, on the free surfaces of said pads (FIG. 2C). The chip P (or the substrate S) is flip-bonded by bringing the adhesive-covered pads PC into contact with corresponding receiving lands or pads PAP (FIG. 2D). Next, the temporary substrate is removed (FIG. 2E), a second thin layer CC2 of conductive adhesive is deposited, also by screen printing, on the newly freed surfaces of the conductive pads (FIG. 2F). Next (FIG. 2G), the chip is brought into contact with the substrate S, care being taken to ensure the pads PC are in alignment with the receiving lands or pads PAS on the surface of said substrate.

As a variant or complement, as much to the first as to the second embodiment of the process of the invention, the conductive adhesive may be selectively deposited (FIGS. 1E, 2C, 2F) on the receiving lands or pads of the chip and/or substrate.

The laser etching operation may be replaced by a chemical or plasma etching operation, by ion-beam or electron-beam milling or even by waterjet cutting or even sawing. However, the latter case does not allow the checkerboard interconnect pattern to be formed.

The thick conductive layer CE may have an isotropic or an anisotropic conductivity. It does not necessarily have to be made from a polymer; as a variant it could, for example, be a metal film, especially a gold film. It is even possible to envision using a composite layer comprising conductive regions (for producing the conductive electrical interconnect pads) and insulating regions (for producing pads having only a mechanical function).

The invention has been described in its application to the bonding of a chip on a substrate but, as indicated above, it may be suitable for the interconnection of any electronic component.

The process according to the first embodiment of the invention has been used to fasten a (“pixilated”) X-ray matrix detector to an electronic acquisition unit, this being an improvement of the hard X-ray microcamera “Caliste 64” described in the article by A. Meuris et al. “Caliste 64, an Innovative CdTe Hard X-ray Micro Camera”, IEEE Trans. Nucl. Sci. 55, No. 2, pp. 778-784, April 2008. The detector D (the chip) essentially consists of a 1 mm-thick CdTe crystal split into 16×16 pixels and having an area of 10 mm×10 mm. The electronic acquisition unit B (the substrate) takes the form of a 10 mm×10 mm×20 mm parallelepiped formed by a stack of eight integrated circuits CI1-CI8 embedded in a resin. Soldered gate contacts CG emerge from the integrated circuits to lie flush with the upper surface of the unit B, where they make contact with a metallization layer CM in order to form an interconnect pattern taking the form of a matrix of 16×16 receiving lands with a pitch of 580 μm and having an external guard ring with a width of 200 μm. The lower surface of the detector has a corresponding interconnect pattern.

This application is particularly constraining because:
the detector D cannot withstand temperatures above 40° C.;
the detector and the electronic unit have very different thermal expansion coefficients from each other: 5.9 ppm/K for the detector, and 18 ppm/K for the electronic unit;
the electronic unit has a substantial thickness (20 mm), thereby making it difficult to apply heat to the interconnect region;
the upper surface of the electronic unit has a planarity of 20 μm over 10 mm, which could lead to contact defects;
the interconnect pattern is dense and comprises a guard ring that would be difficult to produce using conventional techniques; and
the assembly is provided for space applications, thereby limiting the choice of useable materials.

The process of the invention allowed interconnect pads that were 140 to 200 μm in thickness to be produced, these pads had aspect ratios of 3/8 and 4/10, respectively, ensuring a very high tolerance to thermomechanical stresses and also compensating for substrate planarity defects. FIG. 3 shows a cross-sectional view of the interconnect region of the block/detector assembly. The grooves SL caused by the laser etching of the conductive pads will be noted; in the present case, these grooves were produced on purpose in order to form receiving lands PAS by producing a checkerboard pattern in the metal layer CM. In other applications, the power density of the laser could be decreased in order to etch only the thick conductive layer.

1. A flip-chip process for interconnecting an electronic component and a substrate comprises producing at least one interconnect pad by etching a thick conductive layer and adhesively bonding it, by means of at least one conductive adhesive, between a receiving pad or land of said component and a receiving pad or land of said substrate.

2. The process as claimed in claim 1, comprising the following steps:
(a) manufacturing a thick conductive layer;
(b) adhesively bonding it, by means of a conductive adhesive, to an area of an electronic component or of a substrate having at least one receiving pad or land;
(c) producing at least one interconnect pad, in correspondence with said or each receiving pad or land to be connected, by etching said thick layer and said thin layer of conductive adhesive; and
(d) adhesively bonding, by means of a conductive adhesive, said or each interconnect pad to a respective receiving pad or land of a substrate or of an electronic component to be interconnected with said electronic component or said substrate, respectively.

3. The process as claimed in claim 1, comprising the following steps:
(A) manufacturing a thick conductive layer;
(B) adhesively bonding it to a temporary substrate;
(C) etching said thick layer, bonded to said temporary substrate, in order to form an interconnect pattern comprising at least one interconnect pad;
(D) bonding, by means of a conductive adhesive, said or each interconnect pad to a respective receiving pad or land of a substrate or of an electronic component;
(E) debonding said or each interconnect pad from said temporary substrate; and
(F) bonding, by means of a conductive adhesive, said or each interconnect pad to a respective receiving pad or land of a substrate or of an electronic component to be interconnected with said electronic component or said substrate, respectively.

4. The process as claimed in claim 1, in which said electronic component is a chip.

5. The process as claimed in claim 1, in which said or each interconnect pad is produced by laser etching said thick layer.

6. The process as claimed in claim 1, in which said thick layer has a thickness larger than or equal to 100 μm.

7. The process as claimed in claim 1, in which said or at least one said interconnect pad has a height at least equal to half the smallest of its lateral dimensions.

8. The process as claimed in claim 1, comprising a step of setting said or at least one said conductive adhesive at a temperature of 40° C. or less.

9. The process as claimed in claim 1, in which said thick layer consists of said or a said conductive adhesive used for its adhesive bonding, in the set state.

10. The process as claimed in claim 1, in which said or at least one said conductive adhesive is an epoxy resin containing a conductive filler.

11. The process as claimed in claim 1, in which said or each conductive adhesive is deposited by screen printing.

12. The process as claimed in claim 1, in which neither said or each said conductive adhesive nor said thick conductive layer contains lead.
